(19) United States
(12) Patent Application Publication
(10) Pub. No.: US 2013/0105890 A1
(43) Pub. Date: May 2, 2013

(54) VERTICAL NON-DYNAMIC RAM STRUCTURE

(71) Applicant: Chih-Wei Hsiung, Taichung City (TW)

(72) Inventor: Chih-Wei Hsiung, Taichung City (TW)

(21) Appl. No.: 13/282,948

(22) Filed: Oct. 27, 2011

(51) Int. Cl. H01L 29/78

(52) U.S. Cl. 257/331; 257/E29.262

(57) ABSTRACT

A vertical non-dynamic RAM structure comprises a substrate, at least one bit line arranged on the substrate, a plurality of pillars spaced from each other and formed on the bit line with a plurality of troughs formed between them, a plurality of static storage elements respectively connected with the pillar, a plurality of gates respectively formed in one trough and independent to each other without connecting. A dielectric layer separates each gate from the neighboring pillar and the bit line. The present invention provides two independent gates functioning as transistors at two sides of each pillar to control the conduction state of the pillar. Therefore, the present invention needn't etch metal lines to fabricate gates and is thus free of the problem that the gates are hard to satisfy the requirement of smaller feature size.

### FIELD OF THE INVENTION

The present invention relates to a RAM structure, particularly to a vertical non-dynamic RAM structure.

### BACKGROUND OF THE INVENTION

The advance of semiconductor technology not only effectively reduces the size of electronic elements but also obviously decrease the fabrication cost of electronic products. For many years, the semiconductor technology was limited to fabricate planar semiconductor structure via etching, ion implantation, wiring, etc. The smallest chip has been as small as 6F2 so far. However, the technical advance in reducing the feature size has been gradually slowed down, and it is hard to obviously reduce the area occupied by a semiconductor structure on a wafer further. On the other side, the vertical (solid) semiconductor technology is growing mature, wherein the semiconductor elements are vertically grown on a wafer to reduce the area occupied by a transistor in the wafer and reduce the chip size to as small as 4F2. A U.S. Pat. No. 7,326,611 titled with “DRAM Arrays, Vertical Transistor Structures and Methods of Forming Transistor Structure and DRAM Array”, and a US publication No. 2005/0190617 titled with “Folded Bit Line DRAM with Vertical Ultra Thin Body Transistors”, disclosed a vertical pillar transistor and a method for fabricating the same, wherein gates are formed beside the pillar to control the conduction state of the pillar transistor. The gates are normally metal lines formed via etching, attaching to the pillar but not contacting each other. However, the feature size has been reduced to below 40 nm now. It has been a big challenge to etch metal lines into gates beside the pillar because the thickness of the gates is hard to control.

A US publication No. 2009/0256187 titled with “Semiconductor Device Having Vertical Pillar Transistors and Method for Manufacturing the Same” disclosed a gate only formed in a single side of the pillar, wherein a recess is formed via etching the pillar, and wherein metal is filled into the recess to function as the gate. The prior art is exempt from etching metal lines into gates and thus free of the problem of controlling the thickness of the gates. However, the prior art needs to form the recess via etching the pillar, which is also a difficult technology.

### SUMMARY OF THE INVENTION

The primary objective of the present invention is to solve the problem that the gate of a transistor is hard to fabricate with the sub-40 nm process.

To achieve the above-mentioned objective, the present invention proposes a vertical non-dynamic RAM (Random Access Memory) structure, which comprises a substrate, at least one bit line formed on the surface of the substrate, a plurality of pillars spaced from each other and formed on the bit line with a plurality of troughs formed between them, a dielectric layer formed on the surface of one trough, a plurality of static storage elements, and a plurality of gates respectively formed in the trough and independent to each other without connecting. The pillar has a connection end adjacent to the bit line and a top end far away from the connection end. The static storage element is arranged on the top end of the pillar. The dielectric layer separates each gate from the neighboring pillar and the bit line.

When a turn-on voltage is applied to the gates functioning as transistors at two sides of a pillar, the pillar is in a conduction state. Thus, the static storage element is electrically connected with the bit line to store or read data. When a cut-off voltage is applied to one of the gates at one side of a pillar, the pillar is in a cut-off state. Thus, the static storage element is electrically disconnected from the bit line and stops storing or reading data. The static storage element is free of data damage or data errors caused by current leakage.

The present invention is characterized in using two independent gates, which are respectively formed in two grooves at two sides of a pillar transistor, to control the conduction state of the pillar transistor. The present invention is exempted from using an etching process to fabricate gates and thus free of the problem of controlling the thickness of the gates. Via simplifying the gate fabrication process, the present invention can be applied to fabricate the gates of various transistors having different feature sizes. The present invention is particularly suitable for the sub-40 nm process.

### BRIEF DESCRIPTION OF THE DRAWINGS

FIG. 1 is a sectional view schematically showing a vertical non-dynamic RAM structure according to one embodiment of the present invention;

FIGS. 2A-2D are sectional views schematically showing the process of fabricating a vertical non-dynamic RAM structure according to one embodiment of the present invention;

FIG. 3 is a diagram schematically showing the operation of a vertical non-dynamic RAM structure according to one embodiment of the present invention; and

FIG. 4 is a diagram showing the quantification standard deviation in one embodiment of the present invention.

### DETAILED DESCRIPTION OF THE PREFERRED EMBODIMENTS

The technical contents of the present invention are described in detail in cooperation with the drawings below.

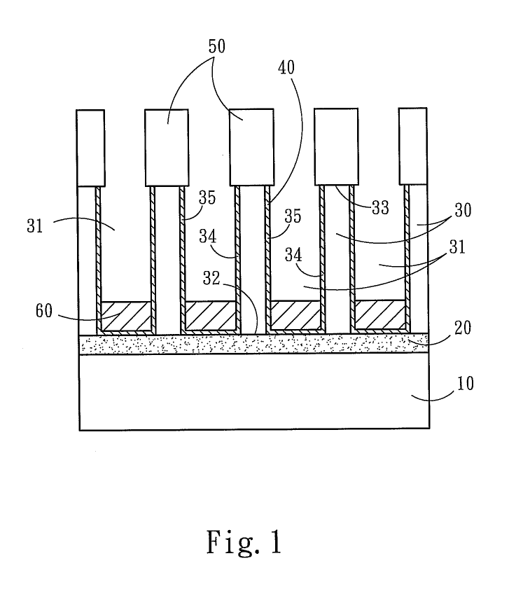

Refer to FIG. 1 a sectional view of a vertical non-dynamic RAM structure according to one embodiment of the present invention. The present invention proposes a vertical non-dynamic RAM structure, which comprises a substrate 10, at least one bit line 20 formed on the surface of the substrate 10, a plurality of pillars 30 spaced from each other and formed on the bit line 20 with a plurality of troughs formed between them 31, a dielectric layer 40 formed on the surface of one trough 31, a plurality of static storage elements 50, and a plurality of gates 60 respectively formed in the trough 31 and independent to each other without connecting. The substrate 10 and the pillars 30 are made of silicon or germanium. The pillar 30 has a connection end 32 adjacent to the bit line 20 and a top end 33 far away from the connection end 32. The top end 33 of the pillar 30 functions as a source/drain, and the connection end 32 of the pillar 30 functions as a drain/source correspondingly. The top end 33 and the connection end 32 are respectively connected with the static storage element 50 and the bit line 20. The source/drain of the top end 33 and the connection end 32 is formed via doping a dopant element to form an N-type or P-type transistor, wherein the dopant element may be an element selected from the group consisting of 2A, 3A, 5A and 6A groups. There are various conventional methods to fabricate the source/drain. However, those are not the focuses of the present invention and will not repeat herein. The static storage element 50 is arranged on the top end 33 of the pillar 30. The dielectric layer 40 separates each gate 60 from the neighboring pillar 30 and the bit line 20. The dielectric layer 40 is made of silicon oxide, silicon dioxide, or a high-permittivity material. In the present invention, the gates 60 are addressed to the pillars 30 functioning as transistors. The gates 60 control the conduction state of each pillar 30. The gates 60 are formed inside the troughs 31 and perpendicular to the bit line 20. The gates 60 and the bit lines 20 jointly form a chessboard-like array. Therefore, the gates 60 function as the word lines of the memory.

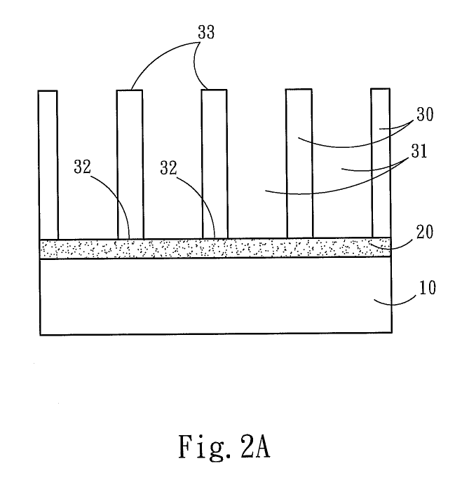

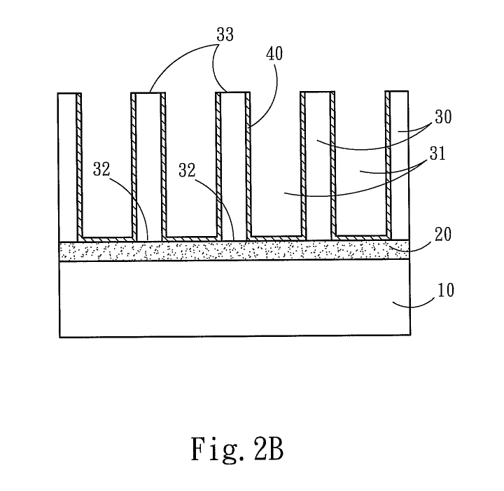

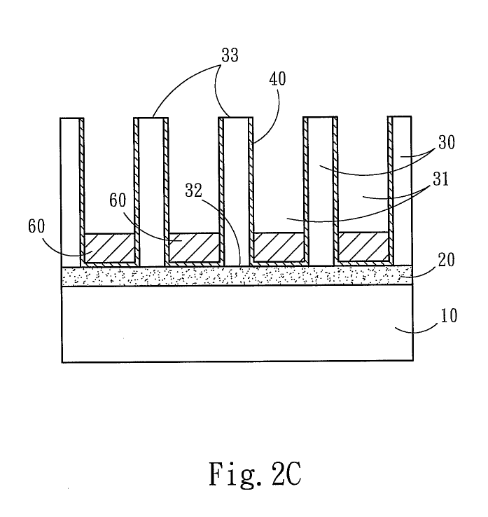

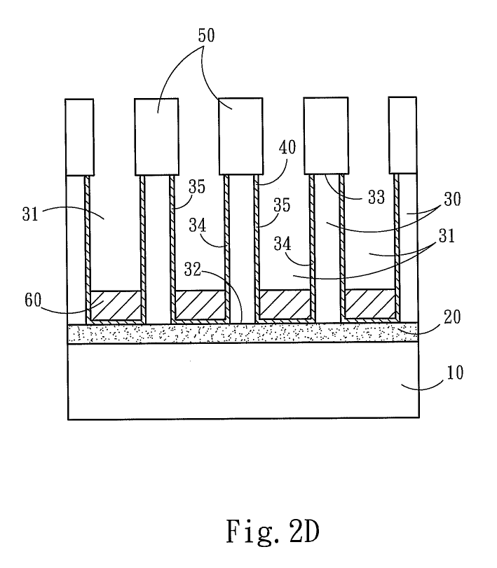

Refer to FIG. 2A. Firstly, a plurality of pillars 30 which are spaced from each other are formed on the bit line 20 with a plurality of troughs 31 formed therebetween. The bit lines 20 may be fabricated via embedding metal lines on the surface of the substrate 10 or implanting ions on the surface of the substrate 10. Refer to FIG. 2B. Next, the dielectric layer 40 is formed on the surface of the trough 31. Refer to FIG. 2C. Next, the gates 60 are formed inside the troughs 31. Refer to FIG. 2D. Then, the static storage elements 50 are formed on the top ends 33 of the pillars 30.

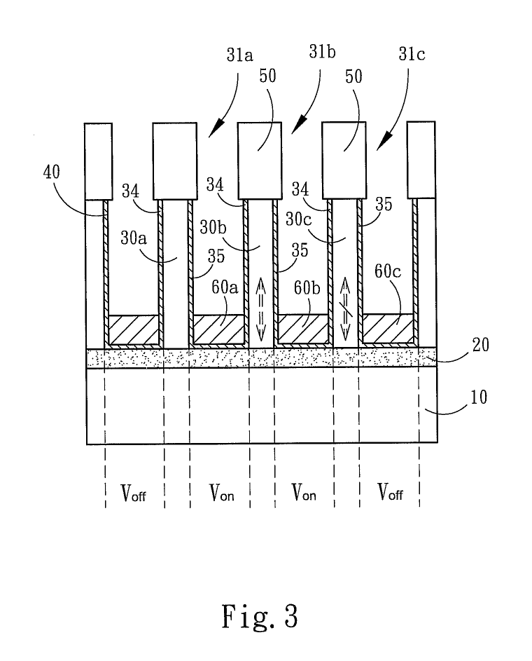

Refer to FIG. 3 for the operation of a vertical non-dynamic RAM structure according to one embodiment of the present invention. Each pillar 30 has a first sidewall 34 and a second sidewall 35 both vertical to the bit lines 20. In FIG. 3, a first pillar 30a, a second pillar 30b and a third pillar 30c are used to exemplify the pillars 30. The first pillar 30a, the second pillar 30b and the third pillar 30c are discretely formed on the bit lines 20. A trough 31a is formed between the first pillar 30a and the second pillar 30b and accommodates a first gate 60a. A trough 31b is formed between the second pillar 30b and the third pillar 30c and accommodates a second gate 60b. A trough 31c is formed beside the second sidewall 35 of the third pillar 30c and accommodates a third gate 60c. The first sidewall 34 and second sidewall 35 of the second pillar 30b respectively connect with the first gate 60a and the second gate 60b. When the first gate 60a and the second gate 60b receive a turn-on voltage Vₒₙ at the same time, the second pillar 30b is in a conduction state and electrically interconnects the static storage element 50 on the top end 33 and the bit line 20 below the connection end 32. Thereby, data can be stored into or read from the static storage element 50. If the third gate 60c receives a cut-off voltage V_{off}, the third pillar 30c between the second gate 60b and the third gate 60c is in a cut-off state and electrically disconnect the top end 33 from the connection end 32. The cut-off voltage V_{off} is a negative voltage, and the turn-on voltage Vₒₙ is a positive voltage in one embodiment. The turn-on voltage Vₒₙ and the cut-off voltage V_{off} may be opposite values, so that the threshold voltage can be increased to prevent from signal reading errors or storing errors caused by erroneous conduction. The pillar 30 may be an N-type transistor or a P-type transistor, depending on the dopant element thereof. The cut-off voltage V_{off} and the turn-on voltage Vₒₙ may alternatively be a positive voltage and a negative voltage respectively.

In other words, the source and drain at two ends of the pillar 30 only can be electrically interconnected when the turn-on voltage Vₒₙ is applied to two gates 60 at two sides of the pillar 30 at the same tune. The source and drain at two ends of the pillar 30 would not be electrically interconnected when the cut-off voltage V_{off} is applied to only one of the gates 60 at two sides of the pillar 30. When the cut-off voltage V_{off} is applied to two gates 60 at two sides of the pillar 30 simultaneously, the pillar 30 is also in a cut-off state.

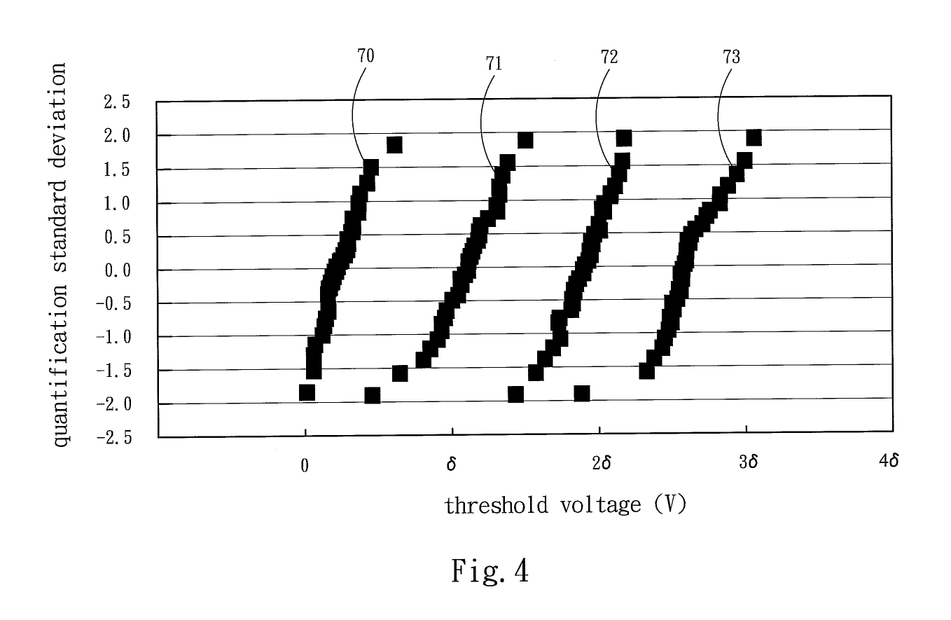

Refer to FIG. 4, wherein a first cut-off voltage curve 71, a second cut-off voltage curve 72 and a third cut-off voltage curve 73 respectively have cut-off voltages of −1V, −2V and −3V. The threshold voltage generated by the third cut-off voltage curve 73 relative to a reference curve 70 is obviously higher than that generated by the first or second cut-off voltage curve 71 or 72. It means that the opposite turn-on voltage Vₒₙ and the cut-off voltage V_{off} can effectively prevent from one-side conduction when the turn-on voltage Vₒₙ is applied to a single gate 60 at one side of the pillar 30. The greater the voltage difference between the turn-on voltage Vₒₙ and the cut-off voltage V_{off}, the higher the threshold voltage, and the more obvious the conduction state and the cut-off state of the pillar 30. As static memories are used in the present invention, current leakage, which may result in erroneous data, is less likely to occur. In FIG. 4, the X-axis is designated with 0, δ, 2δ, 3δ and 4δ (V), which means that the value is not incremented by one Volt but by δ Volt in the X-axis. The pillar 30 may be an N-type transistor or a P-type transistor according to the dopant element used. Therefore, the turn-on voltage Vₒₙ (or the cut-off voltage V_{off}) may be a positive voltage or a negative voltage.

In conclusion, the present invention is characterized in that two independent gates 60 are formed in the troughs 31 at two sides of each pillar 30 to function as transistors and control the conduction state of the pillar 30. Therefore, the present invention is exempted from fabricating the gates with an etching process and thus free of the troublesome problem of controlling the thickness of the gates. Via simplifying the process to fabricate gates, the present invention can be applied to fabricate the gates of transistors having different feature sizes, especially for the gate having a feature size below 40 nm. Further, the present invention uses opposite turn-on voltage Vₒₙ and cut-off voltage V_{off} to increase the threshold voltage and prevent from erroneously reading data caused by erroneous conduction. Therefore, the present invention possesses utility, novelty and non-obviousness and meets the condition for a patent. Thus, the Inventors file the application for a patent. It is appreciated if the patent is approved fast.

The embodiments described above are only to exemplify the present invention but not to limit the scope of the present invention. Any equivalent modification or variation according to the spirit of the present invention is to be also included within the scope of the present invention.

What is claimed is:

1. A vertical non-dynamic random access memory structure, comprising:
a substrate;
at least one bit line arranged on a surface of the substrate;
a plurality of pillars spaced from each other and formed on the bit line with a plurality of troughs formed between them, and including a connection end adjacent to the bit line and a top end far away from the connection end;
a dielectric layer formed a surface of each of the plurality of troughs;
a plurality of static storage elements respectively formed on the top end of the pillar; and
a plurality of gates respectively formed in the trough and independent to each other without connecting, the dielectric layer separating each of the plurality of gates from the neighboring pillars and the bit line.

2. The vertical non-dynamic random access memory structure according to claim 1, wherein the pillar includes a first sidewall and a second sidewall at two sides both vertical to the bit line.

3. The vertical non-dynamic random access memory structure according to claim 2, wherein the top end of the pillar functions as a source/drain and the connection end of the pillar functions as a drain/source correspondingly, and wherein the top end and the connection end are respectively connected with each of the plurality of static storage elements and the bit line.

4. The vertical non-dynamic random access memory structure according to claim 3, wherein the source/drain of the top end and the connection end is formed via doping a dopant element into the pillar.

5. The vertical non-dynamic random access memory structure according to claim 4, wherein the dopant element is an element selected from the group consisting of 2A, 3A, 5A and 6A groups.

6. The vertical non-dynamic random access memory structure according to claim 3, wherein the first sidewall and the second sidewall are respectively corresponding to a first gate and a second gate, and wherein when the first gate and the second gate receive a turn-on voltage at the same time, the pillar is in a conduction state, and the top end and the connection end are electrically interconnected.

7. The vertical non-dynamic random access memory structure according to claim 6, wherein when any of the first gate and the second gate receives a cut-ff voltage, the pillar is in a cut-off state, and the top end is electrically disconnected from the connection end.

8. The vertical non-dynamic random access memory structure according to claim 7, wherein the cut-off voltage and the turn-on voltage are respectively a positive voltage and a negative voltage.

9. The vertical non-dynamic random access memory structure according to claim 7, wherein the cut-off voltage and the turn-on voltage are respectively a negative voltage and a positive voltage.
